(19) United States
(12) Patent Application Publication
(10) Pub. No.: US 2026/0262490 A1
(43) Pub. Date: Sep. 3, 2026

(54) COOLER AND SEMICONDUCTOR DEVICE

(71) Applicants: Astemo, Ltd., Tokyo (JP); TOHOKU UNIVERSITY, Sendai-shi, Miyagi (JP)

(72) Inventors: Shu SASAKI, Hitachinaka-shi (JP); Yusuke NISHIMURA, Hitachinaka-shi (JP); Koji SHIMOYAMA, Sendai-shi (JP)

(21) Appl. No.: 19/163,928

(22) PCT Filed: May 16, 2024
(86) PCT No.: PCT/JP2024/018148

§ 371 Date: Sep. 10, 2025

(30) Foreign Application Priority Data
May 25, 2023 (WO) PCT/JP2023/019536

(51) Int. Cl. H10W 40/22; H10W 40/20

(52) U.S. Cl. CPC H10W 40/228; H10W 40/235

(57) ABSTRACT

In at least one of a plurality of cooling pin rows, an end portion gap area, which is an area between a cooling pin located at an outermost end portion in a flow path width direction and an inner wall surface of a flow path, has a lower flow path resistance than a flow path width direction separation area, which is an area between the cooling pins adjacent to each other in the flow path width direction. In two cooling pin rows adjacent to each other in a main flow direction, a main flow direction separation distance, which is a distance from the cooling pin included in the cooling pin row located on an upstream side to the cooling pin included in the cooling pin row located on a downstream side, is smaller than a main flow direction pin dimension which is a length of the cooling pin included in the cooling pin row located on the downstream side in the main flow direction.

### CROSS REFERENCE TO RELATED APPLICATIONS

This is the U.S. national stage of application No. PCT/JP2024/018148, filed on May 16, 2024. Priority under 35 U.S.C. § 119(a) and 35 U.S.C. § 365(b) is claimed from International Application No. PCT/JP2023/019536 filed May 25, 2023, the disclosure of which is also incorporated herein by reference.

### TECHNICAL FIELD

The present invention relates to a cooler and a semiconductor device.

### BACKGROUND ART

For example, Patent Document 1 discloses a cooler in which a plurality of cooling fins are provided in a cooling medium flow path. In the cooler disclosed in Patent Document 1, heat is transferred from the cooling fins to a cooling medium in the cooling medium flow path to cool a semiconductor module in contact with the cooler. In addition, Patent Document 1 also discloses a cooling fin whose upstream-side transverse cross section is a semicircular shape and whose downstream-side transverse cross section is an equilateral triangle shape extending to the downstream side.

### CITATION LIST

### Patent Document

Patent Document 1: Japanese U.S. Pat. No. 6,616,264

### SUMMARY OF INVENTION

### Technical Problem

The cooler disclosed in Patent Document 1 includes a large number of cooling pins, which are pin-shaped cooling fins, in the flow path. In the cooler, when the cooling medium flowing through the flow path collides with the cooling pin, a flow direction of the cooling medium significantly changes locally by nearly 90°. The cooling medium collides with the cooling pins a plurality of times while flowing from the upstream side to the downstream side. As a result, the cooling medium flows such that the flow direction changes by 90° each time the cooling medium collides with the cooling pin and meanders in the flow path. When the cooling medium meanders in this manner, frequently undergoing significant changes in the flow direction, pressure loss in the flow path increases.

The present invention has been made in view of the above-described problems, and an object of the present invention is to reduce pressure loss in a flow path of a cooling medium in a cooler including a large number of cooling pins.

### Solution to Problem

The present invention employs the following configurations as means for solving the above-described problems.

According to a first aspect of the present invention, a cooler is provided including a plurality of cooling pins provided to extend in a same direction in a flow path of a cooling medium, in which, in a cross section orthogonal to an extension direction of the cooling pins, each of the cooling pins has an upstream-side curved surface portion which is located at a most upstream side of the flow path and is formed by an arc with a first curvature radius, a downstream-side curved surface portion which is located at a most downstream side of the flow path and is formed by an arc with a second curvature radius smaller than the first curvature radius, and a connection surface which connects the upstream-side curved surface portion and the downstream-side curved surface portion, a plurality of cooling pin rows, each of which includes the plurality of cooling pins arranged at equal intervals in a flow path width direction orthogonal to a main flow direction connecting an upstream side and a downstream side of the flow path and the extension direction, are provided and arranged in the main flow direction, in at least one of the plurality of cooling pin rows, an end portion gap area, which is an area between the cooling pin located at an outermost end portion in the flow path width direction and an inner wall surface of the flow path, has a lower flow path resistance than a flow path width direction separation area which is an area between the cooling pins adjacent to each other in the flow path width direction, and, in two cooling pin rows adjacent to each other in the main flow direction, a main flow direction separation distance, which is a distance from the cooling pin included in the cooling pin row located on the upstream side to the cooling pin included in the cooling pin row located on the downstream side, is smaller than a main flow direction pin dimension which is the length of the cooling pin included in the cooling pin row located on the downstream side in the main flow direction.

According to a second aspect of the present invention, there is provided a semiconductor device including the cooler according to the first aspect of the present invention and a semiconductor element configured to be cooled by the cooler.

### Advantageous Effects of Invention

According to the present invention, since the end portion gap area has a lower flow path resistance than the flow path width direction separation area, the flow velocity of the cooling medium flowing through the gap between the cooling pin located at the end portion in the flow path width direction and the inner wall surface of the flow path is higher than the flow velocity of the cooling medium flowing through the gap between the cooling pins. Therefore, the pressure of the gap between the cooling pin located at the end portion in the flow path width direction and the inner wall surface of the flow path is lowered, and the cooling medium that tends to flow along the main flow direction is attracted toward the inner wall surface and flows in a direction inclined with respect to the main flow direction in the flow path. Further, the cooling medium flowing in the direction inclined with respect to the main flow direction is guided to the connection surface connecting the upstream-side curved surface portion having a relatively large curvature radius and the downstream-side curved surface portion having a relatively small curvature radius. Therefore, the cooling medium is likely to flow in the direction inclined with respect to the main flow direction in the flow path. As a result, the force that causes the cooling medium to flow in the direction inclined with respect to the main flow direction is increased, which makes it possible to suppress a significant change in the traveling direction of the cooling medium until the cooling medium passes through a plurality of cooling pins in the main flow direction. Therefore, according to the present invention, it is possible to suppress frequent and significant changes in the flow direction of the cooling medium. As a result, it is possible to reduce the pressure loss in the flow path of the cooling medium in the cooler including a large number of cooling pins.

### BRIEF DESCRIPTION OF DRAWINGS

FIG. 1 A schematic plan view showing a schematic configuration of a cooler according to a first embodiment of the present invention.

FIG. 2 A schematic cross-sectional view showing a schematic configuration of the cooler according to the first embodiment of the present invention.

FIG. 3 A perspective view showing a cooling pin and an upper wall portion provided in the cooler according to the first embodiment of the present invention.

FIG. 4 A schematic horizontal cross-sectional view showing an arrangement of the cooling pins provided in the cooler according to the first embodiment of the present invention.

FIG. 5 A cross-sectional view taken along a plane orthogonal to an extension direction of each cooling pin provided in the cooler according to the first embodiment of the present invention.

FIG. 6 A schematic view showing a positional relationship between a plurality of cooling pins and an inner wall surface of a flow path in the cooler according to the first embodiment of the present invention.

FIG. 7 A view showing a result of simulating a flow velocity distribution around the cooling pin spaced apart from the inner wall surface of the flow path by an end portion gap distance.

FIG. 8 A view showing a result of simulating a pressure distribution around the cooling pin spaced apart from the inner wall surface of the flow path by the end portion gap distance.

FIG. 9 A view showing a result of simulating a flow velocity distribution in a region including a plurality of cooling pins.

FIG. 10 A view showing a result of simulating a pressure distribution in a region including a plurality of cooling pins.

FIG. 11 A schematic plan view showing a schematic configuration of a cooler according to a second embodiment of the present invention.

FIG. 12 A schematic view showing the shape and disposition of cooling pins located in a first region of the cooler according to the second embodiment of the present invention.

FIG. 13 A schematic view showing the shape and disposition of cooling pins located in a third region of the cooler according to the second embodiment of the present invention.

FIG. 14 A schematic partially enlarged cross-sectional view showing a semiconductor device according to a third embodiment of the present invention.

FIG. 15 A schematic plan view showing a modification example of cooling pin rows according to the present invention.

FIG. 16 A schematic view showing the shape and disposition of cooling pins in a cooler according to a fourth embodiment of the present invention.

FIG. 17 A schematic view showing the shape and disposition of cooling pins in a cooler according to a fifth embodiment of the present invention.

FIG. 18 A schematic view showing a shape of a modification example of the cooling pin.

### DESCRIPTION OF EMBODIMENTS

Hereinafter, an embodiment of a cooler and a semiconductor device according to the present invention will be described with reference to the drawings.

### First Embodiment

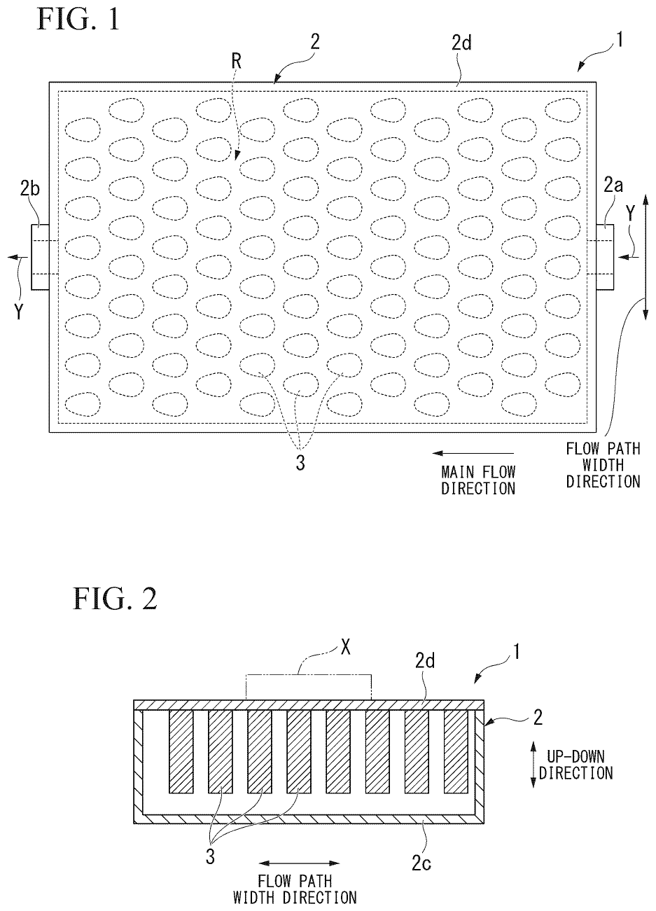

FIG. 1 is a schematic plan view showing a schematic configuration of a cooler 1 according to the present embodiment. In addition, FIG. 2 is a schematic cross-sectional view showing a schematic configuration of the cooler 1 according to the present embodiment. For example, the cooler 1 according to the present embodiment exchanges heat between a heat-generating component X (heat source) installed on an upper surface and a cooling medium Y to cool the heat-generating component X. As shown in FIGS. 1 and 2, the cooler 1 according to the present embodiment includes a housing 2 and cooling pins 3.

A flow path R through which the cooling medium Y flows is formed in the housing 2, and the housing 2 is made of, for example, a metal material having a high thermal conductivity. The housing 2 has a cooling medium supply port 2a for supplying the cooling medium Y to the flow path R and a cooling medium discharge port 2b for discharging the cooling medium Y from the flow path R. As shown in FIG. 1, the cooling medium supply port 2a and the cooling medium discharge port 2b are disposed to face each other with the flow path R interposed therebetween.

In the flow path R of the housing 2, the cooling medium Y flows from the cooling medium supply port 2a toward the cooling medium discharge port 2b. That is, in the flow path R, the cooling medium Y flows from the cooling medium supply port 2a as an upstream side to the cooling medium discharge port 2b as a downstream side.

In the following description, a direction connecting the upstream side and the downstream side of the flow path R (that is, in the present embodiment, a direction connecting the cooling medium supply port 2a and the cooling medium discharge port 2b) is referred to as a main flow direction. In addition, a direction along a width of the flow path R (a width direction of the flow path R orthogonal to the main flow direction) is referred to as a flow path width direction. In addition, an installation posture of the cooler 1 is not particularly limited. For convenience of description, a direction orthogonal to the main flow direction and the flow path width direction is referred to as an up-down direction.

As shown in FIG. 2, in the present embodiment, the housing 2 includes a main body portion 2c and an upper wall portion 2d. The main body portion 2c is formed as a box-shaped container with its upper portion open. In the main body portion 2c, the cooling medium supply port 2a and the cooling medium discharge port 2b are formed.

The upper wall portion 2d is fixed to an upper end of the main body portion 2c and forms an upper portion of the housing 2. The upper wall portion 2d forms the flow path R together with the main body portion 2c. In the present embodiment, an upper surface of the upper wall portion 2d is a mounting surface for the heat-generating component X. In addition, a lower surface of the upper wall portion 2d is a surface on which the cooling pins 3 are formed. That is, the cooling pins 3 are formed to be connected to the lower surface of the upper wall portion 2d. The upper wall portion 2d is integrally molded with, for example, the cooling pins 3.

FIG. 3 is a perspective view showing the cooling pins 3 and the upper wall portion 2d. Further, in FIG. 3, the top and the bottom are inverted. As shown in FIGS. 1 to 3, a plurality of cooling pins 3 are provided. The cooling pins 3 are located inside the flow path R. The cooling pins 3 are made of, for example, the same material as the housing 2.

In the present embodiment, each cooling pin 3 is formed to extend downward from the lower surface of the upper wall portion 2d. That is, the cooler 1 according to the present embodiment includes a plurality of cooling pins 3 provided to extend in the same direction in the flow path R. The extension direction of the cooling pin 3 in the present embodiment is the up-down direction.

The amounts of protrusion of the cooling pins 3 from the upper wall portion 2d are the same. That is, in the present embodiment, the dimensions of each of the cooling pins 3 in the up-down direction are the same. However, the dimensions of the plurality of cooling pins 3 in the up-down direction may be different from each other.

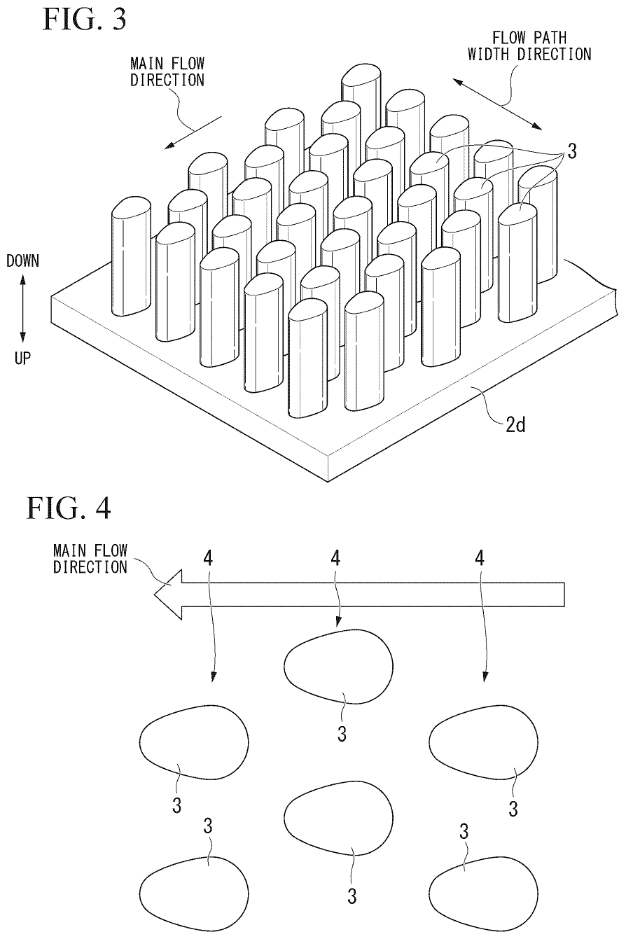

FIG. 4 is a schematic horizontal cross-sectional view showing the arrangement of the cooling pins 3. As shown in FIG. 4, in the present embodiment, the cooling pins 3 are disposed in a staggered pattern as a whole. As shown in FIG. 4, the cooler 1 according to the present embodiment includes cooling pin rows 4 each of which is formed by a plurality of cooling pins 3 arranged in the flow path width direction. A plurality of cooling pin rows 4 are provided and arranged in the main flow direction.

In each cooling pin row 4, the arrangement pitch of the cooling pins 3 in the flow path width direction is the same. That is, the cooling pins 3 included in the same cooling pin row 4 are arranged at equal intervals in the flow path width direction. In addition, in the present embodiment, the arrangement pitch of each of the cooling pins 3 in all of the cooling pin rows 4 is the same.

On the other hand, in two cooling pin rows 4 adjacent to each other in the main flow direction, the phase of the arrangement of the cooling pins 3 is offset by half a pitch. That is, as viewed from the main flow direction, the cooling pin 3 included in the cooling pin row 4 located on the upstream side is disposed between the cooling pins 3 included in the cooling pin row 4 located on the downstream side. In the cooler 1 according to the present embodiment, in two cooling pin rows 4 adjacent to each other in the main flow direction, the cooling pins 3 included in the cooling pin row 4 located on the upstream side and the cooling pins 3 included in the cooling pin row 4 located on the downstream side are disposed in a staggered pattern.

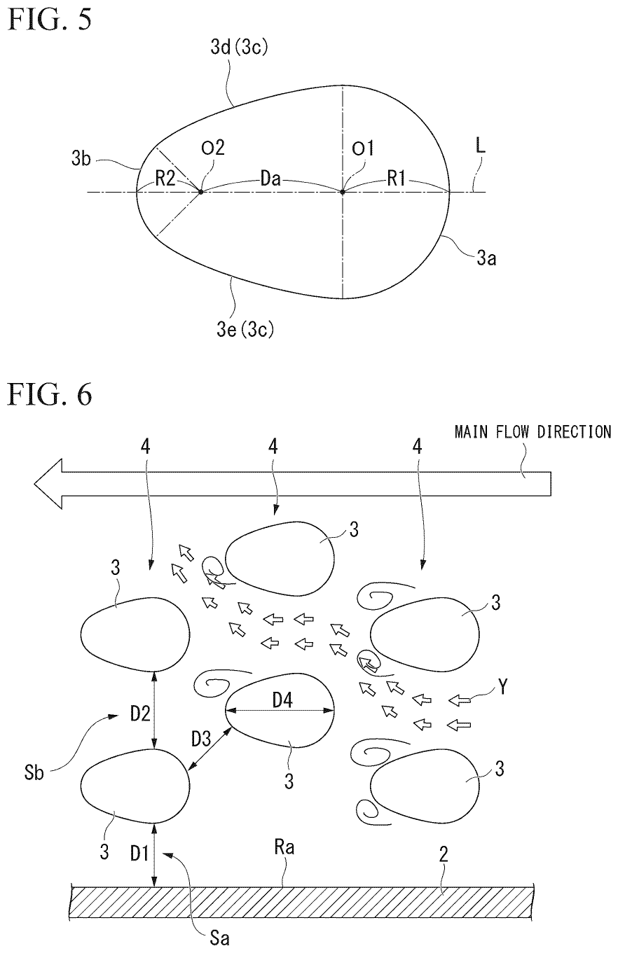

FIG. 5 is a cross-sectional view taken along a plane orthogonal to the extension direction (up-down direction) of each cooling pin 3. As shown in FIG. 5, each cooling pin 3 is formed in a shape having an upstream-side curved surface portion 3a, a downstream-side curved surface portion 3b, and a connection surface 3c in a cross section orthogonal to the extension direction of the cooling pin 3. In addition, the cooling pins 3 are formed to have the same cross-sectional shape taken along the plane orthogonal to the up-down direction in the up-down direction.

The upstream-side curved surface portion 3a is a portion of the cooling pin 3 that is located closest to the upstream side of the flow path R and is formed such that a central portion thereof in the flow path width direction is a curved arc protruding toward the upstream side of the flow path R. The upstream-side curved surface portion 3a is formed to be an arc having a curvature radius R1 (first curvature radius) centered on a center O1. An axis that passes through the center O1 and is parallel to the main flow direction is defined as a central axis L of the cooling pin 3. In the present embodiment, the upstream-side curved surface portion 3a is provided in a range of 90° to the left and right from the central axis L. Further, a formation range of the upstream-side curved surface portion 3a can be changed.

The downstream-side curved surface portion 3b is a portion of the cooling pin 3 that is located closest to the downstream side of the flow path R and is formed such that a central portion thereof in the flow path width direction is a curved arc protruding toward the downstream side of the flow path R. The downstream-side curved surface portion 3b is formed to be an arc having a curvature radius R2 (second curvature radius) centered on a center O2. The curvature radius R2 is smaller than the curvature radius R1. That is, the downstream-side curved surface portion 3b is formed to be an arc having a larger curvature than the upstream-side curved surface portion 3a.

In addition, the center O2 is disposed to overlap with the central axis L passing through the center O1. That is, the center O1 and the center O2 are arranged such that a line segment connecting the center O1 and the center O2 is parallel to the main flow direction. In the present embodiment, the downstream-side curved surface portion 3b is provided in a range of 45° to the left and right from the central axis L. Further, a formation range of the downstream-side curved surface portion 3b can be changed.

The connection surface 3c connects the upstream-side curved surface portion 3a and the downstream-side curved surface portion 3b. In the present embodiment, each cooling pin 3 has a first connection surface 3d, which is the connection surface 3c connecting the upstream-side curved surface portion 3a and the downstream-side curved surface portion 3b, on one side in the flow path width direction. In addition, each cooling pin 3 has a second connection surface 3e, which is the connection surface 3c connecting the upstream-side curved surface portion 3a and the downstream-side curved surface portion 3b, on the other side in the flow path width direction.

In one cooling pin 3, the first connection surface 3d and the second connection surface 3e are smooth surfaces without any bent portion and are closer to each other in the flow path width direction as the first connection surface 3d and the second connection surface 3e extend toward the downstream-side curved surface portion 3b from the upstream-side curved surface portion 3a. In the present embodiment, as shown in FIG. 5, each of the first connection surface 3d and the second connection surface 3e is formed in a slightly curved shape as viewed from the up-down direction.

In addition, the first connection surface 3d and the second connection surface 3e may be flat surfaces that are linear as viewed from the up-down direction. In this case, it is preferable that the first connection surface 3d and the second connection surface 3e are tangents to the upstream-side curved surface portion 3a and the downstream-side curved surface portion 3b. As a result, no bent portions are formed at a boundary between the first connection surface 3d and the upstream-side curved surface portion 3a, a boundary between the first connection surface 3d and the downstream-side curved surface portion 3b, a boundary between the second connection surface 3e and the upstream-side curved surface portion 3a, and a boundary between the second connection surface 3e and the downstream-side curved surface portion 3b.

In addition, in the present embodiment, a plurality of cooling pins 3 provided in the cooler 1 are formed in the same shape. Therefore, the cooling pins 3 have the same distance (center-to-center distance Da) from the center O1 to the center O2.

FIG. 6 is a schematic view showing a positional relationship between a plurality of cooling pins 3 and an inner wall surface Ra of the flow path R. As shown in FIG. 6, in the present embodiment, in two cooling pin rows 4 adjacent to each other in the main flow direction, the cooling pins 3 are disposed in a staggered pattern. Therefore, a distance from the cooling pin 3 included in one of the two cooling pin rows 4 to the inner wall surface Ra is different from a distance from the cooling pin 3 included in the other cooling pin row 4 to the inner wall surface Ra.

Here, in the cooling pin row 4 in which the distance from the cooling pin 3 at an end portion in the flow path width direction to the inner wall surface Ra is short, the distance from the cooling pin 3 at the end portion in the flow path width direction to the inner wall surface Ra is defined as an end portion gap distance D1. That is, the distance from the cooling pin 3 located at the outermost end portion in the flow path width direction to the inner wall surface Ra of the flow path R is the end portion gap distance D1.

In this case, for example, among the cooling pin rows 4 arranged in the main flow direction, the distance from the cooling pin 3 on one end side in the flow path width direction in an even-numbered cooling pin row 4 to the inner wall surface Ra is the end portion gap distance D1. On the other hand, among the cooling pin rows 4 arranged in the main flow direction, the distance from the cooling pin 3 on one end side in the flow path width direction in an odd-numbered cooling pin row 4 to the inner wall surface Ra is greater than the end portion gap distance D1.

On the contrary, in this case, for example, among the cooling pin rows 4 arranged in the main flow direction, the distance from the cooling pin 3 on the other end side in the flow path width direction in the odd-numbered cooling pin row 4 to the inner wall surface Ra is the end portion gap distance D1. On the other hand, among the cooling pin rows 4 arranged in the main flow direction, the distance from the cooling pin 3 on the other end side in the flow path width direction in the even-numbered cooling pin row 4 to the inner wall surface Ra is greater than the end portion gap distance D1.

Further, in the present embodiment, as shown in FIG. 6, the distance between the cooling pins 3 adjacent to each other in the flow path width direction is defined as a flow path width direction separation distance D2. In addition, in two cooling pin rows 4 adjacent to each other in the main flow direction, the distance from the cooling pin 3 included in the cooling pin row 4 located on the upstream side to the cooling pin 3 included in the cooling pin row 4 located on the downstream side is defined as a main flow direction separation distance D3. Furthermore, the length of the cooling pin 3 in the main flow direction is defined as a main flow direction pin dimension D4.

As shown in FIG. 6, in the present embodiment, the end portion gap distance D1 is smaller than the flow path width direction separation distance D2. In addition, the main flow direction separation distance D3 is smaller than the main flow direction pin dimension D4 of the cooling pin 3 included in the cooling pin row 4 located on the downstream side.

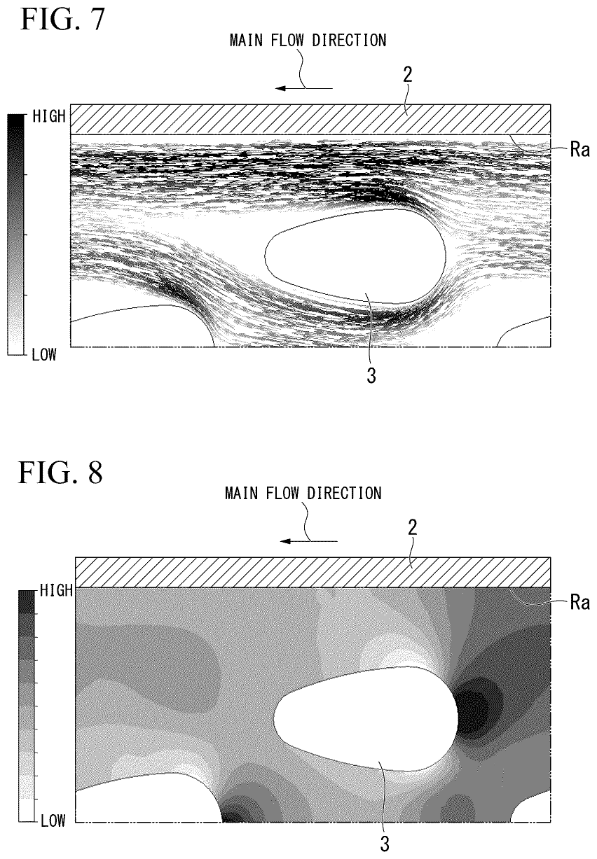

FIG. 7 shows a result of simulating a flow velocity distribution around the cooling pin 3 spaced apart from the inner wall surface Ra of the flow path R by the end portion gap distance D1. In addition, FIG. 8 shows a result of simulating a pressure distribution around the cooling pin 3 spaced apart from the inner wall surface Ra of the flow path R by the end portion gap distance D1.

In the cooler 1 according to the present embodiment, the end portion gap distance D1 is smaller than the flow path width direction separation distance D2. However, in any cooling pin row 4, a gap is formed between the inner wall surface Ra of the flow path R and the cooling pin 3 closest to the innermost wall surface Ra. Therefore, the flow path R has a linear flow path, which extends linearly in the main flow direction, in an area closest to the inner wall surface Ra. As a result, the flow path resistance of an area (end portion gap area Sa) between the inner wall surface Ra and the cooling pin 3 closest to the inner wall surface Ra is lower than the flow path resistance of an area (flow path width direction separation area Sb) between the cooling pins 3.

Therefore, as shown in FIG. 7, the flow velocity of the cooling medium Y flowing through the gap between the cooling pin 3 located at the end portion in the flow path width direction and the inner wall surface Ra of the flow path R is higher than the flow velocity of the cooling medium Y flowing through the gap between the cooling pins 3. As a result, as shown in FIG. 8, the pressure of the gap between the cooling pin 3 located at the end portion in the flow path width direction and the inner wall surface Ra of the flow path R is further lowered.

In addition, when the flow path resistance of the end portion gap area Sa is lower than the flow path resistance of the flow path width direction separation area Sb, the end portion gap distance D1 may be equal to or greater than the flow path width direction separation distance D2.

As described above, the pressure of the gap between the cooling pin 3 located at the end portion in the flow path width direction and the inner wall surface Ra of the flow path R is lowered. Therefore, the cooling medium Y that tends to flow along the main flow direction is attracted toward the inner wall surface Ra and flows in a direction inclined with respect to the main flow direction in the flow path R. Further, the cooling medium Y flowing in the direction inclined with respect to the main flow direction is guided to the connection surface 3c connecting the upstream-side curved surface portion 3a having a relatively large curvature radius and the downstream-side curved surface portion 3b having a relatively small curvature radius. Therefore, the cooling medium Y is likely to flow in the direction inclined with respect to the main flow direction in the flow path R. As a result, the force that causes the cooling medium Y to flow in the direction inclined with respect to the main flow direction is increased, which makes it possible to suppress a significant change in the traveling direction of the cooling medium Y until the cooling medium Y passes through a plurality of cooling pins 3 in the main flow direction.

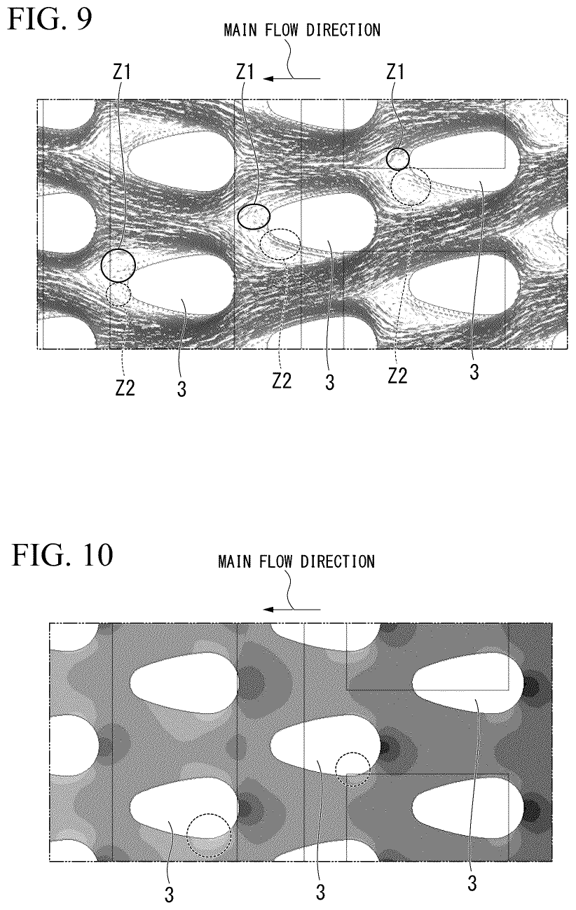

FIG. 9 shows a result of simulating a flow velocity distribution in a region including a plurality of cooling pins 3. FIG. 10 shows a result of simulating a pressure distribution in the region including the plurality of cooling pins 3.

As shown in FIG. 9, two separation vortices (a first separation vortex Z1 and a second separation vortex Z2) are formed on the downstream side of each cooling pin 3. The first separation vortex Z1 is a separation vortex formed on one side of the cooling pin 3 in the flow path width direction. In addition, the second separation vortex Z2 is a separation vortex formed on the other side of the cooling pin 3 in the flow path width direction.

The cooling medium Y flows in the direction inclined with respect to the main flow direction from the upstream side toward the downstream side. In this case, as the flow moves downstream, the pressure rapidly decreases due to the separation of the flow from the connection surface 3c of the cooling pin 3 in a portion (a portion of the cooling pin 3 on the other side in the flow path width direction) surrounded by a circle in FIG. 10. Due to this influence, as shown in FIG. 9, the first separation vortex Z1 increases in size as it moves downstream, and the second separation vortex Z2 decreases in size as it moves downstream. When the sizes of the first separation vortex Z1 and the second separation vortex Z2 are reversed, the flow direction of the cooling medium Y significantly changes by about 90°. That is, in the present embodiment, until the sizes of the first separation vortex Z1 and the second separation vortex Z2 are reversed, the flow of the cooling medium Y does not significantly change, and the cooling medium Y flows linearly in the direction inclined with respect to the main flow direction. As a result, frequent and significant changes in the flow direction of the cooling medium Y are suppressed, which makes it possible to reduce the pressure loss in the flow path R. In the present simulation, it was confirmed that the pressure loss in the flow path R was reduced by 15% while the same thermal resistance was maintained, as compared to a case where the cooling pin having a circular cross section was used.

The cooler 1 having the above-described configuration according to the present embodiment includes a plurality of cooling pins 3 that are provided to extend in the same direction in the flow path R of the cooling medium Y. In addition, in the cross section orthogonal to the extension direction of the cooling pin 3, each cooling pin 3 has the upstream-side curved surface portion 3a, the downstream-side curved surface portion 3b, and the connection surface 3c. The upstream-side curved surface portion 3a is located on the most upstream side of the flow path R and is formed by an arc having the curvature radius R1. The downstream-side curved surface portion 3b is located on the most downstream side of the flow path R and is formed by an arc having the curvature radius R2 smaller than the curvature radius R1. The connection surface 3c connects the upstream-side curved surface portion 3a and the downstream-side curved surface portion 3b.

In addition, the cooler 1 according to the present embodiment includes the cooling pin rows 4. The cooling pin row 4 includes a plurality of cooling pins 3 that are arranged at equal intervals in the flow path width direction orthogonal to the main flow direction connecting the upstream side and the downstream side of the flow path R and the extension direction. In addition, a plurality of cooling pin rows 4 are provided and arranged in the main flow direction. Further, in at least one of the plurality of cooling pin rows 4, the flow path resistance of the end portion gap area Sa is lower than the flow path resistance of the flow path width direction separation area Sb. Furthermore, in two cooling pin rows 4 adjacent to each other in the main flow direction, the main flow direction separation distance D3, which is the distance from the cooling pin 3 included in the cooling pin row 4 located on the upstream side to the cooling pin 3 included in the cooling pin row 4 located on the downstream side, is smaller than the main flow direction pin dimension D4 which is the length of the cooling pin 3 included in the cooling pin row 4 located on the downstream side in the main flow direction.

According to the cooler 1 of the present embodiment, since the flow path resistance of the end portion gap area Sa is lower than the flow path resistance of the flow path width direction separation area Sb, the flow velocity of the cooling medium Y flowing through the gap between the cooling pin 3 located at the end portion in the flow path width direction and the inner wall surface Ra of the flow path R is higher than the flow velocity of the cooling medium Y flowing through the gap between the cooling pins 3. Therefore, the pressure of the gap between the cooling pin 3 located at the end portion in the flow path width direction and the inner wall surface Ra of the flow path R is lowered, and the cooling medium Y that tends to flow along the main flow direction is attracted toward the inner wall surface Ra and flows in the direction inclined with respect to the main flow direction in the flow path R. Further, the cooling medium Y flowing in the direction inclined with respect to the main flow direction is guided to the connection surface 3c connecting the upstream-side curved surface portion 3a having a relatively large curvature radius and the downstream-side curved surface portion 3b having a relatively small curvature radius. Therefore, the cooling medium Y is likely to flow in the direction inclined with respect to the main flow direction in the flow path R. As a result, the force that causes the cooling medium Y to flow in the direction inclined with respect to the main flow direction is increased, which makes it possible to suppress a significant change in the traveling direction of the cooling medium Y until the cooling medium Y passes through a plurality of cooling pins 3 in the main flow direction. Therefore, the cooler 1 according to the present embodiment can suppress frequent and significant changes in the flow direction of the cooling medium Y. Therefore, it is possible to reduce the pressure loss in the flow path R of the cooling medium Y in the cooler including a large number of cooling pins 3.

In addition, in the cooler 1 according to the present embodiment, in two cooling pin rows 4 adjacent to each other in the main flow direction, the cooling pins 3 included in the cooling pin row 4 located on the upstream side and the cooling pins 3 included in the cooling pin row 4 located on the downstream side are disposed in a staggered pattern.

According to the cooler 1 of the present embodiment, the flow path is continuous in the direction inclined with respect to the main flow direction. Therefore, the cooling medium Y is likely to flow in the direction inclined with respect to the main flow direction, and it is possible to reduce the pressure loss as compared to a case where the cooling pins 3 are disposed in a lattice pattern.

In addition, in the cooler 1 according to the present embodiment, each cooling pin 3 has the first connection surface 3d, which is the connection surface 3c connecting the upstream-side curved surface portion 3a and the downstream-side curved surface portion 3b on one side in the flow path width direction, and the second connection surface 3e which is the connection surface 3c connecting the upstream-side curved surface portion 3a and the downstream-side curved surface portion 3b on the other side in the flow path width direction. Further, the first connection surface 3d and the second connection surface 3e are smooth surfaces without any bent portion and are closer to each other in the flow path width direction as the first connection surface 3d and the second connection surface 3e extend toward the downstream-side curved surface portion 3b.

According to the cooler 1 of the present embodiment, the first connection surface 3d and the second connection surface 3e can guide the cooling medium Y in the direction inclined with respect to the main flow direction. Therefore, the cooling medium Y is likely to flow in the direction inclined with respect to the main flow direction, and it is possible to reduce the pressure loss as compared to a case where the cooling pins 3 are disposed in a lattice pattern.

### Second Embodiment

Next, a second embodiment of the present invention will be described with reference to FIGS. 11 to 13. In addition, in the description of the present embodiment, a description of the same portions as in the first embodiment will be omitted or simplified.

FIG. 11 is a schematic plan view showing a schematic configuration of a cooler 1A according to the present embodiment. As shown in FIG. 11, the cooler 1A according to the present embodiment is divided into three regions (a first region A1, a second region A2, and a third region A3) in the main flow direction. The first region A1 is located on the most upstream side among the first region A1, the second region A2, and the third region A3. The second region A2 is located between the first region A1 and the third region A3. The third region A3 is located on the most downstream side among the first region A1, the second region A2, and the third region A3.

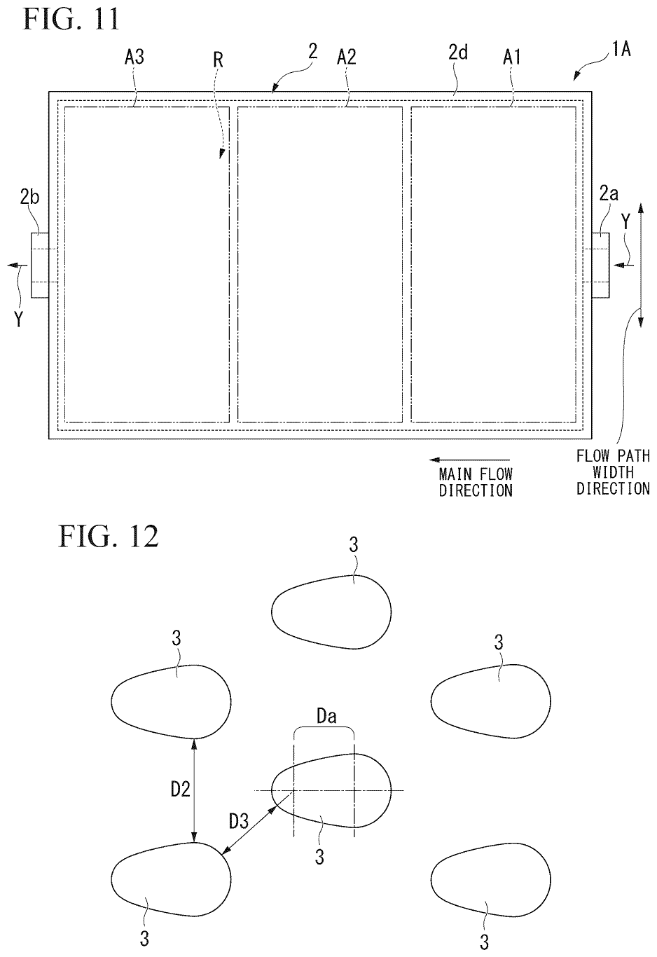

The cooling pins 3 located in the second region A2 have the same shape as the cooling pins 3 in the first embodiment and are disposed in the same manner. FIG. 12 is a schematic view showing the shape and disposition of the cooling pins 3 located in the first region A1. As shown in FIG. 12, the cooling pin 3 located in the first region A1 has a greater center-to-center distance Da than the cooling pin 3 located in the second region A2. However, the curvature radius R1 of the cooling pin 3 located in the first region A1 is equal to the curvature radius R1 of the cooling pin 3 located in the second region A2, and the curvature radius R2 of the cooling pin 3 located in the first region A1 is equal to the curvature radius R2 of the cooling pin 3 located in the second region A2.

Further, the flow path width direction separation distance D2 in the first region A1 is greater than the flow path width direction separation distance D2 in the second region A2, and the main flow direction separation distance D3 in the first region A1 is greater than the main flow direction separation distance D3 in the second region A2. That is, the flow path width direction separation distance D2 in the first region A1 is greater than the flow path width direction separation distance D2 in the second region A2. In addition, the main flow direction separation distance D3 in the first region A1 is greater than the main flow direction separation distance D3 in the second region A2.

In the first region A1, the installation density of the cooling pins 3 is lower than that in the second region A2. Therefore, in the first region A1, the pressure loss is less than that in the second region A2. However, in the first region A1, the thermal resistance is higher than that in the second region A2. That is, the first region A1 is a region in which the reduction in the pressure loss is prioritized over the reduction in the thermal resistance as compared to the second region A2.

However, in the first region A1, the center-to-center distance Da of the cooling pin 3 is greater than that in the second region A2. Therefore, the cooling medium Y can be guided in the direction inclined with respect to the main flow direction as in the second region A2.

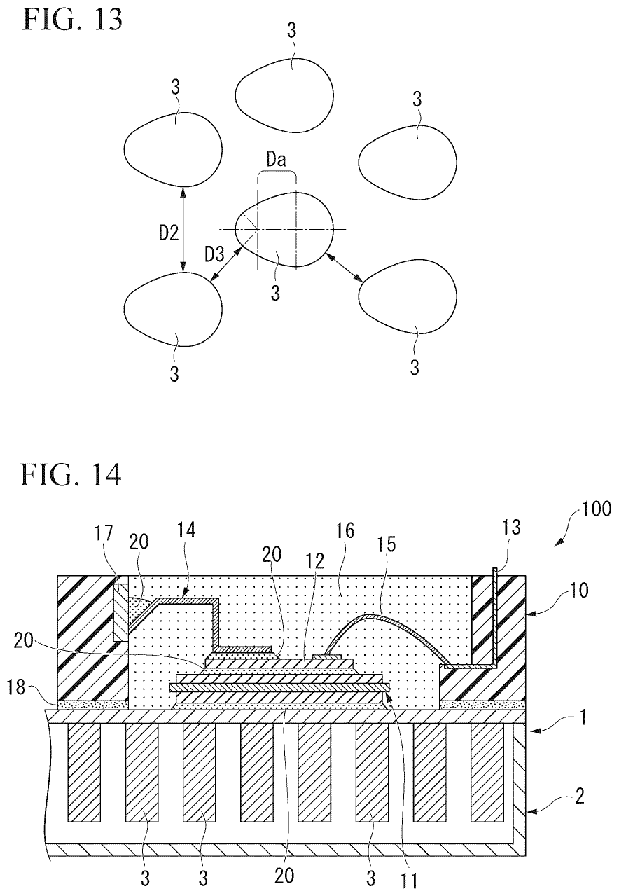

FIG. 13 is a schematic view showing the shape and disposition of the cooling pins 3 located in the third region A3. As shown in FIG. 13, the cooling pin 3 located in the third region A3 has a smaller center-to-center distance Da than the cooling pin 3 located in the second region A2. However, the curvature radius R1 of the cooling pin 3 located in the third region A3 is equal to the curvature radius R1 of the cooling pin 3 located in the second region A2, and the curvature radius R2 of the cooling pin 3 located in the third region A3 is equal to the curvature radius R2 of the cooling pin 3 located in the second region A2.

Further, the flow path width direction separation distance D2 in the third region A3 is smaller than the flow path width direction separation distance D2 in the second region A2, and the main flow direction separation distance D3 in the third region A3 is smaller than the main flow direction separation distance D3 in the second region A2. That is, the flow path width direction separation distance D2 in the third region A3 is smaller than the flow path width direction separation distance D2 in the second region A2. In addition, the main flow direction separation distance D3 in the third region A3 is smaller than the main flow direction separation distance D3 in the second region A2.

In the third region A3, the installation density of the cooling pins is higher than that in the second region A2. Therefore, in the third region A3, the thermal resistance is lower than that in the second region A2. However, in the third region A3, the pressure loss is higher than that in the second region A2. That is, the third region A3 is a region in which the reduction in the thermal resistance is prioritized over the reduction in the pressure loss as compared to the second region A2.

In the third region A3, the center-to-center distance Da of the cooling pin 3 is smaller than that in the second region A2. However, since the cooling pins 3 are densely disposed, the cooling medium Y can be guided in the direction inclined with respect to the main flow direction as in the second region A2.

In the cooler 1A according to the present embodiment, the center-to-center distance Da of the cooling pin 3 decreases stepwise from the first region A1 to the third region A3. In addition, in the cooler 1A according to the present embodiment, the flow path width direction separation distance D2 and the main flow direction separation distance D3 decrease stepwise from the first region A1 to the third region A3.

The cooler 1A having the above-described configuration according to the present embodiment includes the cooling pins 3 having different center-to-center distances Da which are distances from the centers of the upstream-side curved surface portions 3a to the centers of the downstream-side curved surface portions 3b. In addition, the cooling pins 3 having different center-to-center distances Da have the same curvature radius R1 and curvature radius R2. In the cooler 1A having the above-described configuration according to the present embodiment, it is possible to adjust the pressure loss and the thermal resistance while allowing the cooling medium Y to flow linearly in the direction inclined with respect to the main flow direction.

Further, in the cooler 1A according to the present embodiment, the center-to-center distances Da of a plurality of cooling pins 3 arranged in the main flow direction decrease stepwise toward the downstream side in the main flow direction. That is, since the temperature of the cooling medium Y on the upstream side is lower than that on the downstream side, the reduction in the pressure loss is prioritized over the reduction in the thermal resistance. In addition, since the temperature of the cooling medium Y on the downstream side is higher than that on the upstream side, the reduction in the thermal resistance is prioritized over the reduction in the pressure loss. In the cooler 1A according to the present embodiment, it is possible to reduce the pressure loss as a whole and to uniformalize the cooling efficiency of the heat-generating component X in the main flow direction with the cooling pins 3, as compared to a case where the cooling pin having a circular cross section is used.

Further, in the present embodiment, the center-to-center distance Da of the cooling pin 3 decreases stepwise toward the downstream side in the main flow direction. However, the present invention is not limited thereto, and the center-to-center distance Da of the cooling pin 3 may continuously decrease toward the downstream side in the main flow direction.

In addition, in the cooler 1A according to the present embodiment, the main flow direction separation distance D3 varies depending on the position in the main flow direction. In the cooler 1A having the above-described configuration according to the present embodiment, it is possible to adjust the pressure loss and the thermal resistance while allowing the cooling medium Y to flow linearly in the direction inclined with respect to the main flow direction.

Further, in the cooler 1A according to the present embodiment, the main flow direction separation distance D3 decreases stepwise toward the downstream side in the main flow direction. That is, since the temperature of the cooling medium Y on the upstream side is lower than that on the downstream side, the reduction in the pressure loss is prioritized over the reduction in the thermal resistance on the upstream side. In addition, since the temperature of the cooling medium Y on the downstream side is higher than that on the upstream side, the reduction in the thermal resistance is prioritized over the reduction in the pressure loss on the downstream side. In the cooler 1A according to the present embodiment, it is possible to reduce the pressure loss as a whole and to uniformalize the cooling efficiency of the heat-generating component X in the main flow direction with the cooling pins 3, as compared to a case where the cooling pin having a circular cross section is used.

Further, in the present embodiment, the main flow direction separation distance D3 decreases stepwise toward the downstream side in the main flow direction. However, the present invention is not limited thereto, and the main flow direction separation distance D3 may continuously decrease toward the downstream side in the main flow direction.

In addition, for example, the main flow direction separation distance D3 may decrease stepwise or continuously toward the heat-generating component X to be cooled. In this case, the thermal resistance is reduced in a region close to the heat-generating component X, and the heat-generating component X can be efficiently cooled.

### Third Embodiment

Next, a third embodiment of the present invention will be described with reference to FIG. 14. In addition, in the description of the present embodiment, a description of the same portions as in the first embodiment will be omitted or simplified.

FIG. 14 is a schematic partially enlarged cross-sectional view showing a semiconductor device 100 according to the present embodiment. The semiconductor device 100 according to the present embodiment is, for example, a power conversion device that performs power conversion between a battery and a motor. The semiconductor device 100 includes a cooler 1, a resin case 10, an insulating circuit substrate 11, a semiconductor chip 12 (semiconductor element), an external terminal 13, a lead frame 14, a lead wire 15, and a sealing material 16.

The cooler 1 is the cooler 1 according to the first embodiment. In addition, the semiconductor device 100 according to the present embodiment may include the cooler 1A according to the second embodiment instead of the cooler 1. The cooler 1 cools the semiconductor chip 12 and the like. The cooler 1 collects heat transferred from the semiconductor chip 12 through the insulating circuit substrate 11 and the like with a cooling liquid. The cooler 1 functions as a base member that supports the insulating circuit substrate 11 and the like.

The resin case 10 is adhered to the cooler 1 with an adhesive layer 18 interposed therebetween. The resin case 10 holds a bus bar 17. In addition, the resin case 10 has an opening portion through which the semiconductor chip 12 and the like are accommodated. As shown in FIG. 14, the bus bar 17 is held in a state in which a joint portion with the lead frame 14 is exposed toward the inside of the opening portion.

The insulating circuit substrate 11 has an insulating ceramic substrate and metal layers formed on both surfaces of the insulating ceramic substrate. The metal layer formed on the front side of the insulating ceramic substrate is electrically connected to the semiconductor chip 12 and forms a portion of a conductive circuit. The metal layer formed on the back side of the insulating ceramic substrate forms a portion of a heat transfer path that transmits heat transferred from the semiconductor chip 12 and the like to the cooler 1.

The insulating ceramic substrate can be made of, for example, aluminum oxide (Al₂O₃), aluminum nitride (AlN), or silicon-based ceramics (Si₃Ni₄). In addition, the metal layer can be made of, for example, copper (Cu) or aluminum (Al).

The semiconductor chip 12 is, for example, a chip on which an insulated gate bipolar transistor (IGBT), a SiC-MOSFET, or the like is formed. The semiconductor chip 12 is mounted on the insulating circuit substrate 11. In the present embodiment, one semiconductor chip 12 is mounted on one insulating circuit substrate 11. Further, a plurality of semiconductor chips 12 may be mounted on one insulating circuit substrate 11. The semiconductor chip 12 can be formed using a silicon (Si) semiconductor. In addition, the semiconductor chip 12 can also be formed using a wide bandgap semiconductor such as a silicon carbide (SiC) semiconductor or a gallium nitride (GaN) semiconductor.

The external terminal 13 is held with respect to the resin case 10. A plurality of external terminals 13 are provided, and each of the external terminals 13 is connected to the semiconductor chip 12 through the lead wire 15. The semiconductor chip 12 is controlled from the outside through the external terminals 13.

The lead frame 14 is a plate-shaped conductive member that connects the semiconductor chip 12 and the bus bar 17. For example, two lead frames 14 are connected to one semiconductor chip 12. The lead frame 14 is a conductive member through which a large amount of current flows, as compared to the lead wire 15 through which a control signal flows. Further, the lead frame 14 is connected to the semiconductor chip 12 and the bus bar 17. However, the lead frame 14 may connect the insulating circuit substrate 11 and the bus bar 17.

The lead wire 15 is a conductive member that connects the semiconductor chip 12 and the external terminal 13. That is, the semiconductor chip 12 and the external terminal 13 are electrically connected to each other by so-called wire bonding.

The inside of the opening portion of the resin case 10 is filled with the sealing material 16. The sealing material 16 covers the insulating circuit substrate 11, the semiconductor chip 12, and the like to prevent the insulating circuit substrate 11, the semiconductor chip 12, and the like from coming into contact with air and the like. The sealing material 16 can be made of, for example, silicone gel.

In addition, in the semiconductor device 100 according to the present embodiment, solder 20, which is a brazing material, is provided at various locations. Specifically, as shown in FIG. 14, the solder 20 is provided at the joint portion between the lead frame 14 and the bus bar 17. That is, the lead frame 14 and the bus bar 17 are joined to each other by the solder 20. In addition, the solder 20 is provided at a joint portion between the lead frame 14 and the semiconductor chip 12. That is, the lead frame 14 and the semiconductor chip 12 are joined to each other by the solder 20.

Further, the solder 20 is provided between the semiconductor chip 12 and the insulating circuit substrate 11. That is, the semiconductor chip 12 and the insulating circuit substrate 11 are joined to each other by the solder 20. In addition, the solder 20 is provided between the insulating circuit substrate 11 and the cooler 1. That is, the insulating circuit substrate 11 and the cooler 1 are joined to each other by the solder 20.

Furthermore, the lead wire 15 and the external terminal 13 are also joined to each other by the solder, which is not shown in FIG. 14. In addition, the lead wire 15 and the semiconductor chip 12 are also joined to each other by the solder.

The semiconductor device 100 according to the present embodiment includes the cooler 1 according to the first embodiment. Therefore, it is possible to reduce the pressure loss in the flow path R of the cooling medium Y.

The preferred embodiments of the present invention have been described above with reference to the accompanying drawings, but it goes without saying that the present invention is not limited to the above-described embodiments. The various shapes and combinations of each constituent member shown in the above-described embodiments are merely examples and can be variously changed based on design requirements and the like without departing from the gist of the present invention.

For example, in the above-described embodiments, the configuration in which the cooling pin rows 4 have the same number of cooling pins 3 has been described. However, the present invention is not limited thereto. That is, in the present invention, the cooling pin rows 4 may have different numbers of cooling pins 3.

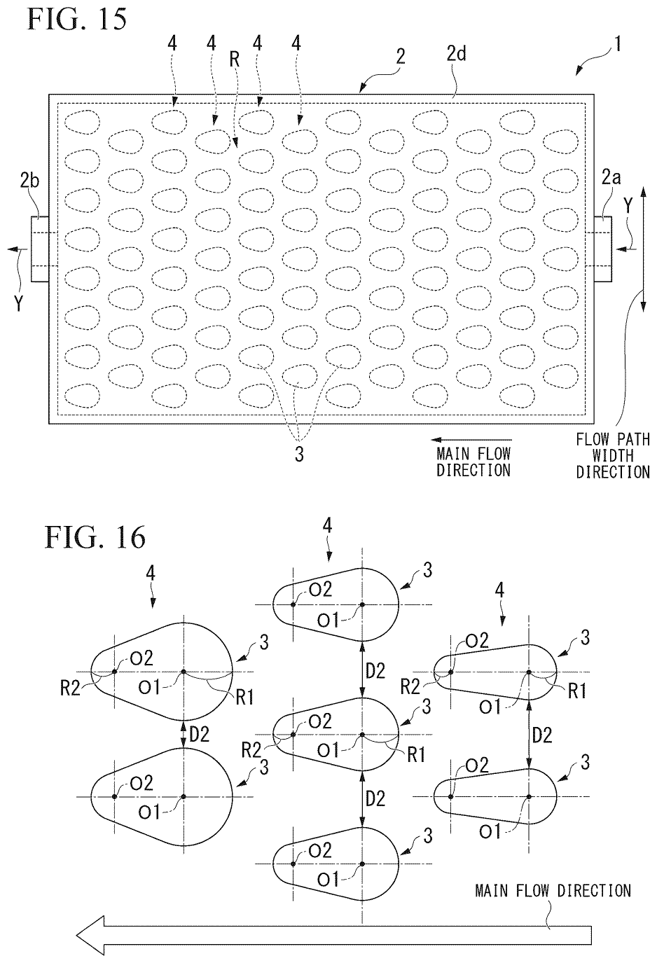

FIG. 15 is a schematic plan view showing a modification example of the cooling pin rows in the present invention. For example, as shown in FIG. 15, the cooling pin row 4 that has relatively one more cooling pin 3 and the cooling pin row 4 that has relatively one fewer cooling pin 3 may be alternately arranged in the main flow direction.

### Fourth Embodiment

Next, a fourth embodiment of the present invention will be described with reference to FIG. 16. In addition, in the description of the present embodiment, a description of the same portions as in the first embodiment will be omitted or simplified.

FIG. 16 is a schematic view showing the shape and disposition of the cooling pins of the cooler according to the present embodiment. As shown in FIG. 16, in the present embodiment, the curvature radius R1 and the curvature radius R2 of the cooling pin 3 vary depending on the position of the cooling pin 3 in the main flow direction. For example, even in the same region (the first region A1, the second region A2, or the third region A3) defined in FIG. 11, the curvature radius R1 and the curvature radius R2 of the cooling pin 3 vary depending on the position of the cooling pin 3 in the main flow direction.

In the present embodiment, the curvature radius R1 of the cooling pin 3 located on the upstream side in the main flow direction is smaller than the curvature radius R1 of the cooling pin 3 located on the downstream side in the main flow direction. In FIG. 16, the curvature radius R1 of the cooling pin 3 included in the cooling pin row 4 located on the most upstream side is smaller than the curvature radius R1 of the cooling pin 3 included in the cooling pin row 4 at the center in the main flow direction and the curvature radius R1 of the cooling pin 3 included in the cooling pin row 4 located on the most downstream side in the main flow direction. In addition, in FIG. 16, the curvature radius R1 of the cooling pin 3 included in the cooling pin row 4 located on the most downstream side is larger than the curvature radius R1 of the cooling pin 3 included in the cooling pin row 4 at the center in the main flow direction and the curvature radius RI of the cooling pin 3 included in the cooling pin row 4 located on the most upstream side in the main flow direction.

Further, in the present embodiment, the curvature radius R2 of the cooling pin 3 located on the upstream side in the main flow direction is smaller than the curvature radius R2 of the cooling pin 3 located on the downstream side in the main flow direction. In FIG. 16, the curvature radius R2 of the cooling pin 3 included in the cooling pin row 4 located on the most upstream side is smaller than the curvature radius R2 of the cooling pin 3 included in the cooling pin row 4 at the center in the main flow direction and the curvature radius R2 of the cooling pin 3 included in the cooling pin row 4 located on the most downstream side in the main flow direction. In addition, in FIG. 16, the curvature radius R2 of the cooling pin 3 included in the cooling pin row 4 located on the most downstream side is larger than the curvature radius R2 of the cooling pin 3 included in the cooling pin row 4 at the center in the main flow direction and the curvature radius R2 of the cooling pin 3 included in the cooling pin row 4 located on the most upstream side in the main flow direction.

Furthermore, in FIG. 16, the arrangement pitch of the cooling pins 3 (for example, the distance interval between the centers O1) is the same in each cooling pin row 4. In this case, the flow path width direction separation distance D2 in the cooling pin row 4 located on the most upstream side in FIG. 16 is increased, and the pressure loss in the cooling pin row 4 located on the most upstream side is reduced. Therefore, the pressure loss of the entire cooler can also be reduced.

Further, in the present embodiment, the surface area of the cooling pin 3 included in the cooling pin row 4 located on the most upstream side is reduced, and the flow velocity in the cooling pin row 4 located on the most upstream side is reduced. However, the temperature of the cooling medium Y decreases as the position moves toward the upstream side. Therefore, in the present embodiment, the cooling performance is equalized in the main flow direction.

Further, in the present embodiment, the cooling pins 3 included in different cooling pin rows 4 may have different center-to-center distances Da. In addition, in the present embodiment, the cooling pins 3 included in different cooling pin rows 4 may have the same center-to-center distance Da.

### Fifth Embodiment

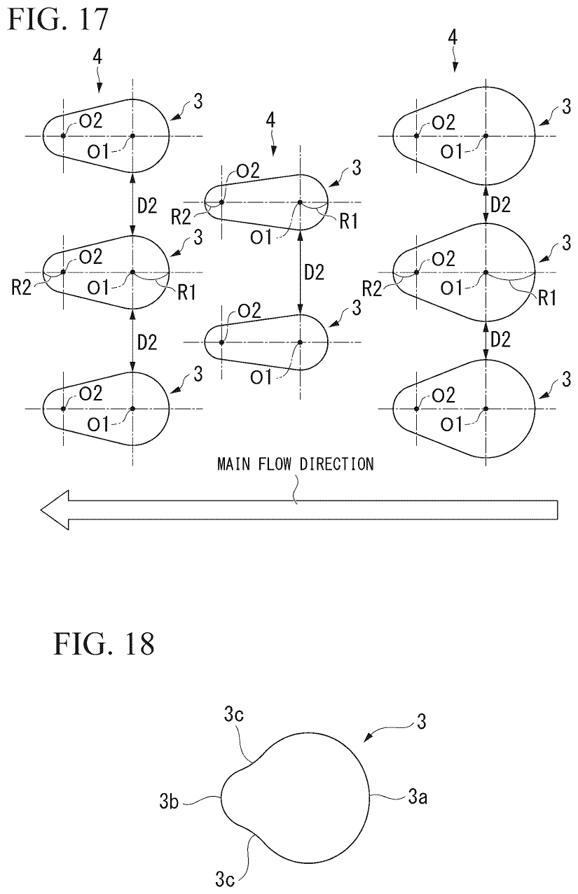

Next, a fifth embodiment of the present invention will be described with reference to FIG. 17. In addition, in the description of the present embodiment, a description of the same portions as in the fourth embodiment will be omitted or simplified.

FIG. 17 is a schematic view showing the shape and disposition of cooling pins of a cooler according to the present embodiment. As shown in FIG. 17, in the present embodiment, the curvature radius R1 and the curvature radius R2 of the cooling pin 3 vary depending on the position of the cooling pin 3 in the main flow direction as in the fourth embodiment.

In the present embodiment, the curvature radius R1 of the cooling pin 3 located on the most upstream side in the main flow direction is larger than the curvature radius R1 of the cooling pin 3 located at the center in the main flow direction and the curvature radius R1 of the cooling pin 3 located on the most downstream side in the main flow direction. Specifically, in FIG. 17, the curvature radius R1 of the cooling pin 3 included in the cooling pin row 4 located on the most upstream side is larger than the curvature radius R1 of the cooling pin 3 included in the cooling pin row 4 at the center in the main flow direction and the curvature radius R1 of the cooling pin 3 included in the cooling pin row 4 located on the most downstream side in the main flow direction. In addition, in FIG. 17, the curvature radius R1 of the cooling pin 3 included in the cooling pin row 4 located on the most downstream side is larger than the curvature radius R1 of the cooling pin 3 included in the cooling pin row 4 at the center in the main flow direction. That is, in FIG. 17, the cooling pin 3 in the cooling pin row 4 at the center in the main flow direction has the smallest curvature radius R1.

In the present embodiment, the curvature radius R2 of the cooling pin 3 located on the most upstream side in the main flow direction is larger than the curvature radius R2 of the cooling pin 3 located at the center in the main flow direction and the curvature radius R2 of the cooling pin 3 located on the most downstream side in the main flow direction. Specifically, in FIG. 17, the curvature radius R2 of the cooling pin 3 included in the cooling pin row 4 located on the most upstream side is larger than the curvature radius R2 of the cooling pin 3 included in the cooling pin row 4 at the center in the main flow direction and the curvature radius R2 of the cooling pin 3 included in the cooling pin row 4 located on the most downstream side in the main flow direction. In addition, in FIG. 17, the curvature radius R2 of the cooling pin 3 included in the cooling pin row 4 located on the most downstream side is larger than the curvature radius R2 of the cooling pin 3 included in the cooling pin row 4 at the center in the main flow direction. That is, in FIG. 17, the cooling pin 3 included in the cooling pin row 4 at the center in the main flow direction has the smallest curvature radius R2.

Furthermore, in FIG. 17, the arrangement pitch (for example, the distance interval between the centers O1) of the cooling pins 3 is the same in each cooling pin row 4. In this case, the flow path width direction separation distance D2 in the cooling pin row 4 located on the most upstream side in FIG. 17 is the smallest, and the flow velocity in the cooling pin row 4 located on the most upstream side increases. In addition, the surface area of the cooling pin 3 included in the cooling pin row 4 located on the most upstream side increases. As a result, the cooling performance at the position where the cooling pin row 4 located on the most upstream side is provided is improved. Therefore, it is possible to further cool the heat-generating component X located on the most upstream side.

Further, for example, the curvature radius R1 of the cooling pin 3 included in the cooling pin row 4 at the location where the heat-generating component X is disposed may be larger than the curvature radius RI of the cooling pin 3 included in other cooling pin rows 4 while maintaining the arrangement pitch. In addition, similarly, the curvature radius R2 of the cooling pin 3 included in the cooling pin row 4 at the location where the heat-generating component X is disposed may be larger than the curvature radius R2 of the cooling pin 3 included in other cooling pin rows 4 while maintaining the arrangement pitch.

That is, of the cooling pin row 4 located on the upstream side and the cooling pin row 4 located on the downstream side, at least one of the curvature radius R1 and the curvature radius R2 of all of the cooling pins 3 included in the cooling pin row 4 closer to the heat-generating component X may be larger than the corresponding curvature radius of the cooling pins 3 included in the cooling pin row 4 farther from the heat-generating component X. In this case, it is possible to locally improve the cooling performance of the location where the heat-generating component X is disposed.

Further, in the present embodiment, the cooling pins 3 included in different cooling pin rows 4 may have different center-to-center distances Da. In addition, in the present embodiment, the cooling pins 3 included in different cooling pin rows 4 may have the same center-to-center distance Da.

The fourth embodiment and the fifth embodiment of the present invention have been described above with reference to the accompanying drawings. However, it goes without saying that the present invention is not limited to the above-described embodiments. The various shapes and combinations of each constituent member shown in the above-described embodiments are merely examples and can be variously changed based on design requirements and the like without departing from the gist of the present invention.

For example, in the above-described embodiments, as shown in FIG. 18, a cooling pin 3 in which a connection surface 3c connecting the upstream-side curved surface portion 3a and the downstream-side curved surface portion 3b is curved and recessed can also be used.

In addition, the above-described embodiments can also be described as, for example, the following supplementary notes.

### Supplementary Note 1

A cooler including:
a plurality of cooling pins provided to extend in a same direction in a flow path of a cooling medium,
in which, in a cross section orthogonal to an extension direction of the cooling pins, each of the cooling pins has
an upstream-side curved surface portion which is located at a most upstream side of the flow path and is formed by an arc with a first curvature radius,
a downstream-side curved surface portion which is located at a most downstream side of the flow path and is formed by an arc with a second curvature radius smaller than the first curvature radius, and
a connection surface which connects the upstream-side curved surface portion and the downstream-side curved surface portion,
a plurality of cooling pin rows, each of which includes the plurality of cooling pins arranged at equal intervals in a flow path width direction orthogonal to a main flow direction connecting an upstream side and a downstream side of the flow path and the extension direction, are provided and arranged in the main flow direction,
in at least one of the plurality of cooling pin rows, an end portion gap area, which is an area between the cooling pin located at an outermost end portion in the flow path width direction and an inner wall surface of the flow path, has a lower flow path resistance than a flow path width direction separation area which is an area between the cooling pins adjacent to each other in the flow path width direction, and
in two cooling pin rows adjacent to each other in the main flow direction, a main flow direction separation distance, which is a distance from the cooling pin included in the cooling pin row located on the upstream side to the cooling pin included in the cooling pin row located on the downstream side, is smaller than a main flow direction pin dimension which is a length of the cooling pin included in the cooling pin row located on the downstream side in the main flow direction.

### Supplementary Note 2

The cooler according to Supplementary Note 1,
in which, in the two cooling pin rows adjacent to each other in the main flow direction, the cooling pins included in the cooling pin row located on the upstream side and the cooling pins included in the cooling pin row located on the downstream side are disposed in a staggered pattern.

### Supplementary Note 3

The cooler according to Supplementary Note 1 or 2,
in which each of the cooling pins has a first connection surface, which is the connection surface connecting the upstream-side curved surface portion and the downstream-side curved surface portion on one side in the flow path width direction, and a second connection surface, which is the connection surface connecting the upstream-side curved surface portion and the downstream-side curved surface portion on the other side in the flow path width direction, and
the first connection surface and the second connection surface are smooth surfaces without any bent portion and are closer to each other in the flow path width direction as the first connection surface and the second connection surface extend toward the downstream-side curved surface portion.

### Supplementary Note 4

The cooler according to any one of Supplementary Notes 1 to 3,
in which the cooling pins have different center-to-center distances, which are distances from centers of the upstream-side curved surface portions to centers of the downstream-side curved surface portions, and the cooling pins having different center-to-center distances have the same first curvature radius and the same second curvature radius.

### Supplementary Note 5

The cooler according to Supplementary Note 4,
in which the center-to-center distances of a plurality of the cooling pins arranged in the main flow direction decrease stepwise or continuously toward the downstream side in the main flow direction.

### Supplementary Note 6

The cooler according to any one of Supplementary Notes 1 to 5,
in which the main flow direction separation distance varies depending on a position in the main flow direction.

### Supplementary Note 7

The cooler according to Supplementary Note 6,
in which the main flow direction separation distance decreases stepwise or continuously toward the downstream side in the main flow direction.

### Supplementary Note 8

The cooler according to Supplementary Note 6,
in which the main flow direction separation distance decreases stepwise or continuously as the cooling pins are located closer to a heat source to be cooled.

### Supplementary Note 9

A semiconductor device including:
the cooler according to any one of Supplementary Notes 1 to 8; and a semiconductor element configured to be cooled by the cooler.

### Supplementary Note 10

The cooler according to Supplementary Note 1,
in which the cooling pin included in the cooling pin row located on the upstream side is different from the cooling pin included in the cooling pin row located on the downstream side in at least one of the first curvature radius and the second curvature radius.

### Supplementary Note 11

The cooler according to Supplementary Note 10,
in which at least one of the first curvature radius and the second curvature radius of the cooling pin included in the cooling pin row located on the upstream side is smaller than the first curvature radius and the second curvature radius of the cooling pin included in the cooling pin row located on the downstream side.

### Supplementary Note 12

The cooler according to Supplementary Note 10,
in which, of the cooling pin row located on the upstream side and the cooling pin row located on the downstream side, at least one of the first curvature radius and the second curvature radius of all of the cooling pins included in the cooling pin row closer to a heat-generating component is larger than the first curvature radius and the second curvature radius of the cooling pins included in the cooling pin row farther from the heat-generating component.

### REFERENCE SIGNS LIST

1 Cooler
1A Cooler
2 Housing
3 Cooling pin
3a Upstream-side curved surface portion
3b Downstream-side curved surface portion
3c Connection surface
3d First connection surface
3e Second connection surface
4 Cooling pin row
100 Semiconductor device
A1 First region
A2 Second region
A3 Third region
D1 End portion gap distance
D2 Flow path width direction separation distance
D3 Main flow direction separation distance
D4 Main flow direction pin dimension
Da Center-to-center distance
Sa End portion gap area
Sb Flow path width direction separation area
L Central axis
O1 Center
O2 Center
R Flow path
R1 Curvature radius
R2 Curvature radius
Ra Inner wall surface
X Heat-generating component
Y Cooling medium
Z1 First separation vortex
Z2 Second separation vortex

1. A cooler comprising:
a plurality of cooling pins provided to extend in a same direction in a flow path of a cooling medium,
wherein, in a cross section orthogonal to an extension direction of the cooling pins, each of the cooling pins has
an upstream-side curved surface portion which is located at a most upstream side of the flow path and is formed by an arc with a first curvature radius,
a downstream-side curved surface portion which is located at a most downstream side of the flow path and is formed by an arc with a second curvature radius smaller than the first curvature radius, and
a connection surface which connects the upstream-side curved surface portion and the downstream-side curved surface portion,
a plurality of cooling pin rows, each of which includes the plurality of cooling pins arranged at equal intervals in a flow path width direction orthogonal to a main flow direction connecting an upstream side and a downstream side of the flow path and the extension direction, are provided and arranged in the main flow direction,
in at least one of the plurality of cooling pin rows, an end portion gap area, which is an area between the cooling pin located at an outermost end portion in the flow path width direction and an inner wall surface of the flow path, has a lower flow path resistance than a flow path width direction separation area which is an area between the cooling pins adjacent to each other in the flow path width direction, and
in two cooling pin rows adjacent to each other in the main flow direction, a main flow direction separation distance, which is a distance from the cooling pin included in the cooling pin row located on the upstream side to the cooling pin included in the cooling pin row located on the downstream side, is smaller than a main flow direction pin dimension which is a length of the cooling pin included in the cooling pin row located on the downstream side in the main flow direction.

2. The cooler according to claim 1,
wherein, in the two cooling pin rows adjacent to each other in the main flow direction, the cooling pins included in the cooling pin row located on the upstream side and the cooling pins included in the cooling pin row located on the downstream side are disposed in a staggered pattern.

3. The cooler according to claim 1,
wherein each of the cooling pins has a first connection surface, which is the connection surface connecting the upstream-side curved surface portion and the downstream-side curved surface portion on one side in the flow path width direction, and a second connection surface, which is the connection surface connecting the upstream-side curved surface portion and the downstream-side curved surface portion on the other side in the flow path width direction, and
the first connection surface and the second connection surface are smooth surfaces without any bent portion and are closer to each other in the flow path width direction as the first connection surface and the second connection surface extend toward the downstream-side curved surface portion.

4. The cooler according to claim 1,
wherein the cooling pins have different center-to-center distances, which are distances from centers of the upstream-side curved surface portions to centers of the downstream-side curved surface portions, and the cooling pins having different center-to-center distances have the same first curvature radius and the same second curvature radius.

5. The cooler according to claim 4,
wherein the center-to-center distances of a plurality of the cooling pins arranged in the main flow direction decrease stepwise or continuously toward the downstream side in the main flow direction.

6. The cooler according to claim 1,
wherein the main flow direction separation distance varies depending on a position in the main flow direction.

7. The cooler according to claim 6,
wherein the main flow direction separation distance decreases stepwise or continuously toward the downstream side in the main flow direction.

8. The cooler according to claim 6,
wherein the main flow direction separation distance decreases stepwise or continuously as the cooling pins are located closer to a heat source to be cooled.

9. A semiconductor device comprising:
the cooler according to claim 1; and
a semiconductor element configured to be cooled by the cooler.

10. The cooler according to claim 1,
wherein the cooling pin included in the cooling pin row located on the upstream side is different from the cooling pin included in the cooling pin row located on the downstream side in at least one of the first curvature radius and the second curvature radius.

11. The cooler according to claim 10,
wherein at least one of the first curvature radius and the second curvature radius of the cooling pin included in the cooling pin row located on the upstream side is smaller than the first curvature radius and the second curvature radius of the cooling pin included in the cooling pin row located on the downstream side.

12. The cooler according to claim 10,
wherein, of the cooling pin row located on the upstream side and the cooling pin row located on the downstream side, at least one of the first curvature radius and the second curvature radius of all of the cooling pins included in the cooling pin row closer to a heat-generating component is larger than the first curvature radius and the second curvature radius of the cooling pins included in the cooling pin row farther from the heat-generating component.
